(19) United States
(12) Patent Application Publication
(10) Pub. No.: US 2011/0228946 A1
(43) Pub. Date: Sep. 22, 2011

(54) COMFORT NOISE GENERATION METHOD AND SYSTEM

(75) Inventors: Yaakov CHEN, Rishon Le-tzion (IL); Mark Raifel, Ra'anana (IL)

(73) Assignee: DSP Group Ltd., Herzelia (IL)

(21) Appl. No.: 12/728,285

(22) Filed: Mar. 22, 2010

(51) Int. Cl. H03G 3/00

(52) U.S. Cl. 381/61

(57) ABSTRACT

A method for Comfort Noise Generation (CNG) comprising the steps of recording information of Background Noise (BGN); generating white noise samples; and generating Comfort Noise (CN) by applying coefficients that are extracted from said information of BGN on White Noise (WN) samples.

### FIELD OF THE INVENTION

The present invention relates generally to the field of comfort noise generation and more particularly to a method and system for comfort noise generation in communication networks with discontinuous transmission or as artificial background noise to be used by echo canceller systems or by communication systems that implement mute function.

### BACKGROUND OF THE INVENTION

Comfort Noise (CN) is an artificial background noise that is used in a variety of audio applications. One application that uses comfort noise is communication network with discontinuous transmission (DTX) such as VoIP, GSM or DECT, where the CN is used to fill silence intervals/periods (also known as transmission gaps) at the receiver end when the silence is not transmitted explicitly. Silence intervals are common in speech applications such as phone call conversations. It is known that speech gaps in transmission should be filled with some kind of noise to prevent the phenomena of complete silence at the receiver end, which creates a discomfort feeling to the listener.

Other types of applications that make use of CN are echo cancellers and suppressors. CN is used as a non-linear processing (NLP) that replaces residual echo. These applications refer to a situation where a far-end user and near-end user are conducting a conversation and the generation of an artificial background noise is required in order to provide the far-end with a background noise, instead of complete silence, when only the far-end speaks.

Yet another type of application where CN could be used by applications that implements a mute functionality, such as telephone systems that enable a first participant (near-end) to disable its microphone and turn into a listen-only participant (muted user). In this mode it may be desired to provide a CN for the far-end listener to avoid the feeling of complete silence at the far-end participant side.

Producing CN usually consists of two steps: first the background noise is learned and then it is generated. There are several methods for implementing Comfort Noise Generation (CNG), including:
(a) Pseudo Random Noise Generator where CNG Learn is implemented by estimating Variance and Level of the actual BGN and CNG Generate that generates Noise with a given variance and level. This method has drawback of a non-natural sound of the CN.
(b) Store and Play Actual Background Noise
   CNG Learn: Store actual BGN, CNG Generator: Play the stored noise with random starting points. This method has drawback of repletion of the CN that is noticed by the listener and thus, doesn't sound as true background noise.
(c) All-pole modeling spectral shaping filter (G.711 Appendix II)
   CNG Learn: Estimate all-pole filter coefficients and level estimation from the actual BGN. All-pole filter coefficients estimate the envelope of the signal. Hence, this method has a drawback of excitation estimation signal. Generally white noise is used as excitation signal.
   CNG Generate: Shape white noise with all-pole shaping filter. (With the envelope of the actual BGN, all-pole filter is auto regressive AR)
(d) ARMA (Auto Regressive Moving Average) spectral shaping filter
   CNG Learn: Generate ARMA filter coefficients and level estimation from the actual BGN. The output is similar to All-pole modeling spectral shaping filter. This method has the same drawback.
   CNG Generate: Shape white noise with all-pole shaping filter. This method has a drawback of excitation.
(e) Shaping Filter in frequency Domain
   CNG Learn: Generate Frequency Domain (FTT, DCT) filter coefficients and level estimation
   CNG Generate: Shape white noise with Frequency Domain filters coefficients in frequency domain.
   This method has a drawback of not acquiring good matching to background noise.
   Thus, there is a need for a simple method and system for generation of CN, which can be implemented by a low-cost system and has good spectral and level matching with BGN.

### SUMMARY OF THE INVENTION

An aspect of an embodiment of the invention relates to a method and system for comfort noise generation (CNG) that provides good spectral and level matching with BGN and is simple for implementation, requires very limited hardware and software resources.

An aspect of an embodiment of the invention relates to a method and system for CNG that is based on two phases: recording actual BGN and estimating its level in a first learning phase and applying coefficients that are extracted from the recorded BGN on White Noise (WN) samples wherein the Comfort Noise (CN) is adjusted according to the BGN level estimation of the learn phase.

An aspect of an embodiment of the invention relates to a method and system for CNG that can be implemented in communication networks with discontinuous transmission, or in an echo canceller system, or in communication system that implements a mute function by a muted user.

In an exemplary embodiment in accordance with the disclosed subject matter there is disclosed a method for Comfort Noise Generation (CNG) comprising the steps of recording information of Background Noise (BGN); generating white noise samples; and generating Comfort Noise (CN) by applying coefficients that are extracted from the information of BGN on White Noise (WN) samples.

In an exemplary embodiment in accordance with the disclosed subject matter the step of recording information of Background Noise includes estimation of actual BNG level, and the step of generating Comfort Noise (CN) by applying coefficients that are extracted from the information of BGN on White Noise (WN) samples includes level adjustment according to the estimation of actual BNG level.

In an exemplary embodiment in accordance with the disclosed subject applying coefficients that are extracted from the information of BGN on White Noise (WN) for generating the n'th sample of CN is performed by implementing a formula that is basically

$$Y ( n ) = {\sum }_{i = 0}^{N - 1} {C ( i )}^{*} X ( n - i )$$

wherein i goes from 0 to N−1, where N is the number of coefficients of each BGN sample, C[i] is the n'th sample of the recorded information of BGN, and X[n] is the n'th sample of the WN.

In an exemplary embodiment in accordance with the disclosed subject matter the CNG is used in a communication network with discontinuous transmission in order to fill silence periods, the communication network comprising a transmitter and a receiver and wherein the information of BGN is recorded during a predefined period that starts at the beginning of a silence period and wherein the transmitter keeps transmission for enabling the receiver to collect information on the BGN.

In an exemplary embodiment in accordance with the disclosed subject matter the CNG is used during silence periods, when the transmitter does not transmit data to the receiver.

In an exemplary embodiment in accordance with the disclosed subject matter the CNG is used in an echo canceller system having a near-end and a far-end; wherein the Background noise (BGN) is recorded during periods when both far-end and near-end are inactive.

In an exemplary embodiment in accordance with the disclosed subject matter the Comfort Noise (CN) replaces residual echo at times when only far end is active.

In an exemplary embodiment in accordance with the disclosed subject matter the CNG is used in a communication system that implements a mute function by a muted user, for providing a listener to the muted user with Comfort Noise during periods of the mute function activation.

In an exemplary embodiment in accordance with the disclosed subject matter BGN is recorded during periods when the mute function is inactive and both the muted user and the listener are inactive; and wherein the CNG is activated during periods when the mute function is activated.

In an exemplary embodiment in accordance with the disclosed subject matter recording information of Background Noise is implemented by a cyclic buffer with a pointer that tracks the most updated background noise information.

In an exemplary embodiment in accordance with the disclosed subject matter the generation of Comfort Noise is implemented by software.

In an exemplary embodiment in accordance with the disclosed subject matter the generation of Comfort Noise is implemented by hardware.

In an exemplary embodiment in accordance with the disclosed subject matter the generation of Comfort Noise is implemented by a combination of software and hardware elements.

In an exemplary embodiment in accordance with the disclosed subject matter there is disclosed a system for Comfort Noise Generation, comprising: a unit for recording information of Background Noise (BGN) during periods when only BGN is present; a White-Noise generation unit; a unit for generating Comfort Noise (CN); wherein the CN is generated by applying coefficients that are extracted from the information of BGN on White Noise (WN) samples that were generated by the White-Noise generation unit.

In an exemplary embodiment in accordance with the disclosed subject matter the unit for recording information of Background Noise (BGN) includes a functionality of estimation of actual BNG level, and wherein the unit for generating CN includes level adjustment according to the estimation of actual BNG level.

In an exemplary embodiment in accordance with the disclosed subject matter the unit for generating Comfort Noise implements a function that is basically described by the formula

$$Y ( n ) = {\sum }_{i = 0}^{N - 1} {C ( i )}^{*} X ( n - i )$$

### BRIEF DESCRIPTION OF THE DRAWINGS

The present invention will be understood and appreciated more fully from the following detailed description taken in conjunction with the drawings. Identical structures, elements or parts, which appear in more than one figure, are generally labeled with a same or similar number in all the figures in which they appear, wherein:

FIG. 1 is a block diagram of a general communication network including a transmitter and a receiver implementing a generic DTX scheme (Prior Art).

FIG. 2A is a block diagram of a first communication network scheme including a far end, a near end and an echo cancelling circuit (Prior Art).

FIG. 2B is a block diagram of a second communication network scheme including a far end, a near end and an echo cancelling circuit (Prior Art).

FIG. 2C is a block diagram of a third communication network scheme including a far end, a near end and an echo cancelling circuit (Prior Art).

FIG. 3 is a flow chart showing the steps of CNG learn and CNG generate in accordance with the disclosed subject matter in a DTX scheme.

FIG. 4A is a schematic description of the timing when BGN is recorded in accordance with the disclosed subject matter in a DTX scheme.

FIG. 4B is a schematic description of four mutual states in an echo cancelling system.

FIG. 5 is a flow chart describing the steps of implementing CNG for replacing silence in the receiver in a network during DTX in accordance with the disclosed subject matter.

FIG. 6 is a flow chart describing the steps of implementing CNG for replacing residual echo in an audio system that includes an echo cancelling function in accordance with the disclosed subject matter.

FIG. 7 is a flow chart describing the steps of implementing CNG in a phone system that implements a mute function in accordance with the disclosed subject matter.

FIG. 8 is a block diagram describing the usage of CNG in a phone system that implements a mute function in accordance with the disclosed subject matter.

FIG. 9 is a general description of a circuit that implements comfort noise generator function in accordance with the disclosed subject matter.

### DETAILED DESCRIPTION OF THE INVENTION

The present invention will be understood and appreciated more fully from the following detailed description taken in conjunction with the drawings. Identical structures, elements or parts, which appear in more than one figure, are generally labeled with a same or similar number in all the figures in which they appear, wherein:

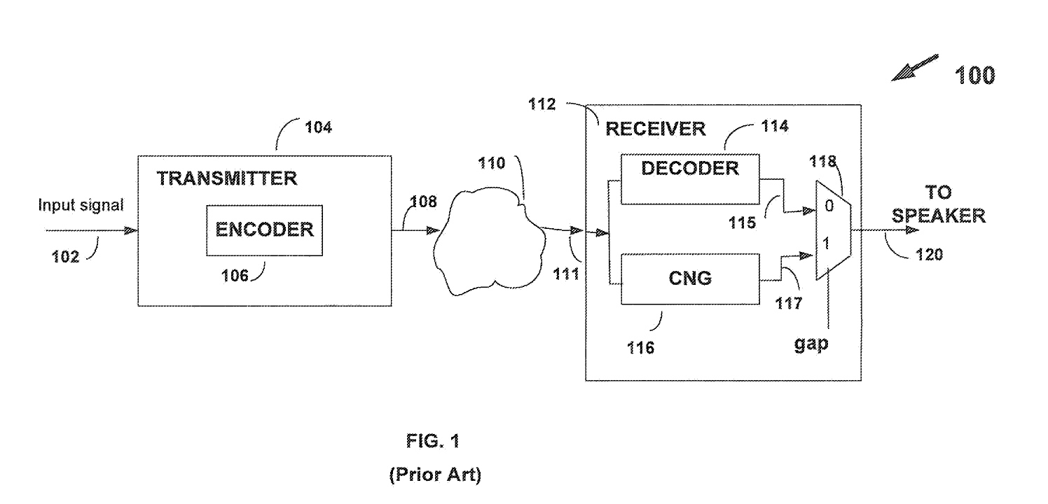

FIG. 1 (Prior Art) is a block diagram of a transmitter-receiver system 100, wherein a transmitter 104 including an encoder 106 encodes an input signal 102 and transmits an output signal 108 to the air 110 to be received as input signal 111 in a receiver 112. The receiver includes a decoder 114, a Comfort Noise Generator (CNG) 116 and a selector unit 118 that selects between a decoded signal 115 and CNG output 117 to provide output signal 120 that is typically used as an input signal to a speaker. In this example the CNG is used during gaps in transmission, when the receiver detects a gap in the transmission, (for example when a Voice Activity Detection (VAD) circuit detects a silence period) the CNG generates Comfort Noise (CN) frames that are played continuously until VAD=1 (Voice Activity detector recognizes voice activity). The present invention discloses a method and system for implementing Comfort Noise Generator (CNG).

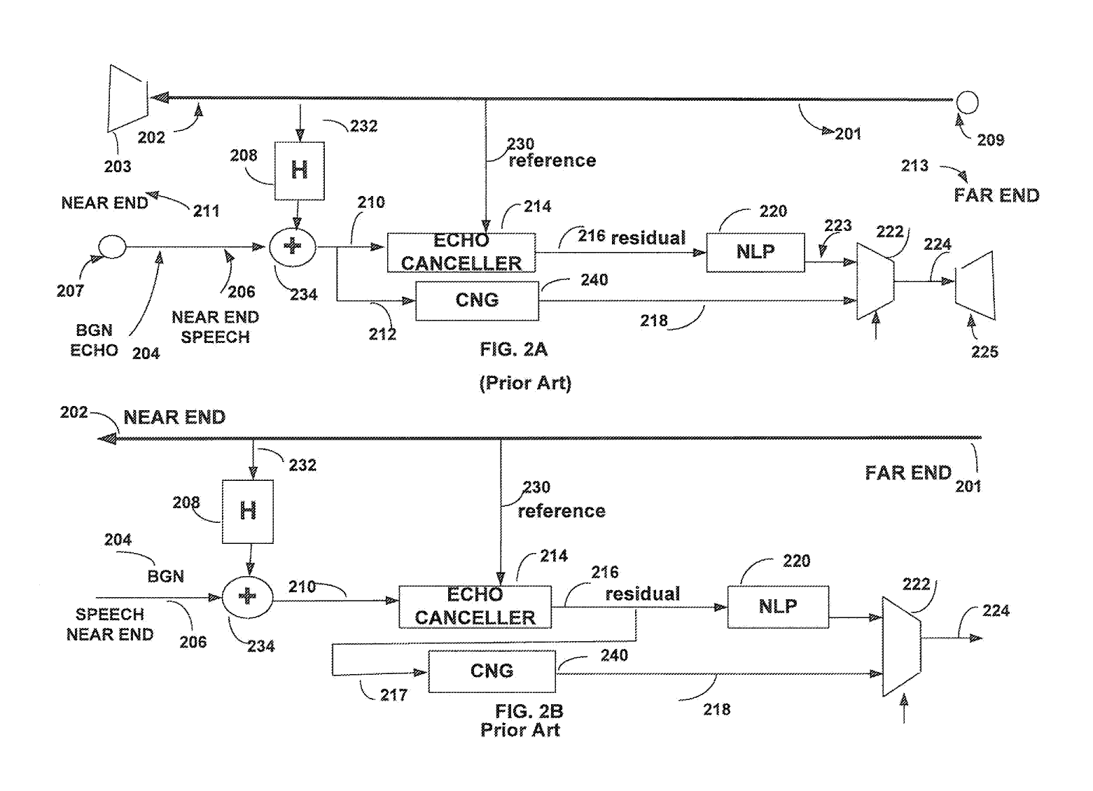

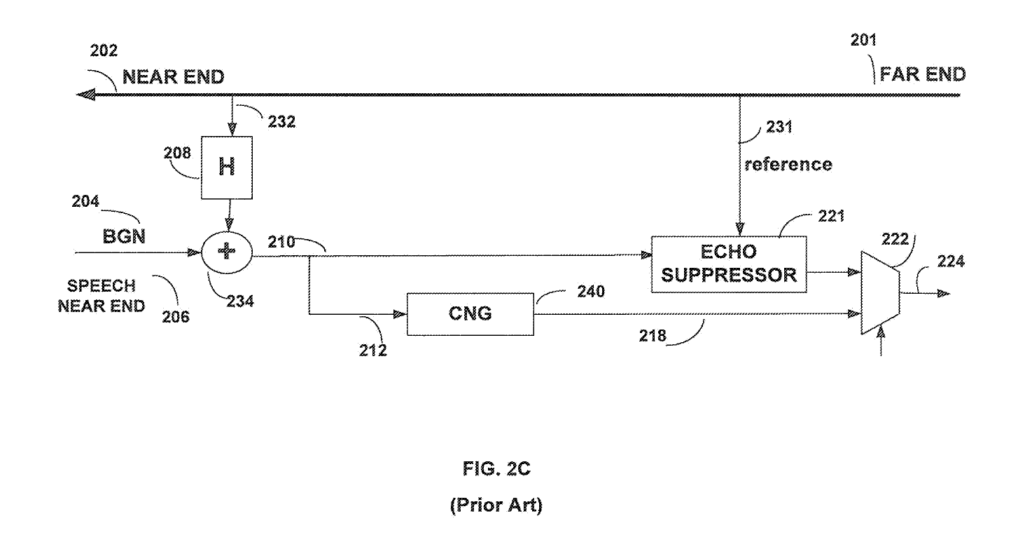

FIG. 2A (Prior Art) shows a block diagram of another application that uses a Comfort Noise Generator (CNG) for replacing the Echo Canceller (EC) 214 and NLP 220 when only a far end 213 is speaking. The block diagram shows a Far End (FE) 213 (typically using a microphone 209 and speakers 225), a Near End (NE) 211 (typically using a microphone 207 and speakers 203) when a conversation takes place far-end's signal 201 is sent towards the near-end's direction and near-end's signal 206 is sent towards far-end 213 direction. Block 208 stands for the system that generates any type of echo. For example, in an acoustic system, it stands for acoustic echo including direct echo path from the speakers to the microphones and including reflected echo due to reverberation of the acoustic environment. In electric (network) echo system, block 208 stands for the 4-wire/2-wire converter (hybrid) that generates electric echo. The input signal 210 consists of the superposition of echo signal (output of 208) whenever far-end talker speaks and near-end signal 206. The near-end signal consists of near-end speech 207 whenever near-end talker speaks and background noise. Signal 210 proceeds in two channels: to echo canceller control unit 214 and to CNG 240. As shall be further described, CNG 240 is used when there is only a far-end speech (or a far-end signal in the line system case) where the only signal that is desired to be played at the far-end side is a background noise free from any residual echo. However signal 210 that is input to the CNG 240 may be sampled by CNG 240 at all times in order to store background noise samples as shall be further described. Residual signal 216 is being input to Non Linear Processor (NLP) which is designed to eliminate residual echo and the NLP output 223 is provided to the far-end speaker 225.

The present disclosure refers to one of four possible cases of the systems as shown in FIG. 2A. The four cases are:

(a) Only far-end speaks;

(b) Only near-end speaks;

(c) Both ends speaking simultaneously;

(d) Nobody speaks.

CNG generation is required only at the first case—when only FE speaks. In this case, which is identified by echo canceller control unit 214; there is a need to provide only BGN- to the FE. At this state only FE speaks and the only signal that is desired at FE side is BGN that is used to prevent the inconvenience of complete silent at the FE speaker. On the other hand, CNG learn is desired to be applied during the last case, when nobody speaks and only actual background noise exists at the output of the echo canceller 214 and CNG 240,

FIGS. 2B and 2C are variations of the scheme that is shown in FIG. 2A.

FIG. 2B shows a case where residual signal 216 is being input to CNG 240 instead of signal 210.

FIG. 2C shows a case where echo canceller 214 and NLP 220 are replaced by an echo suppressor 221.

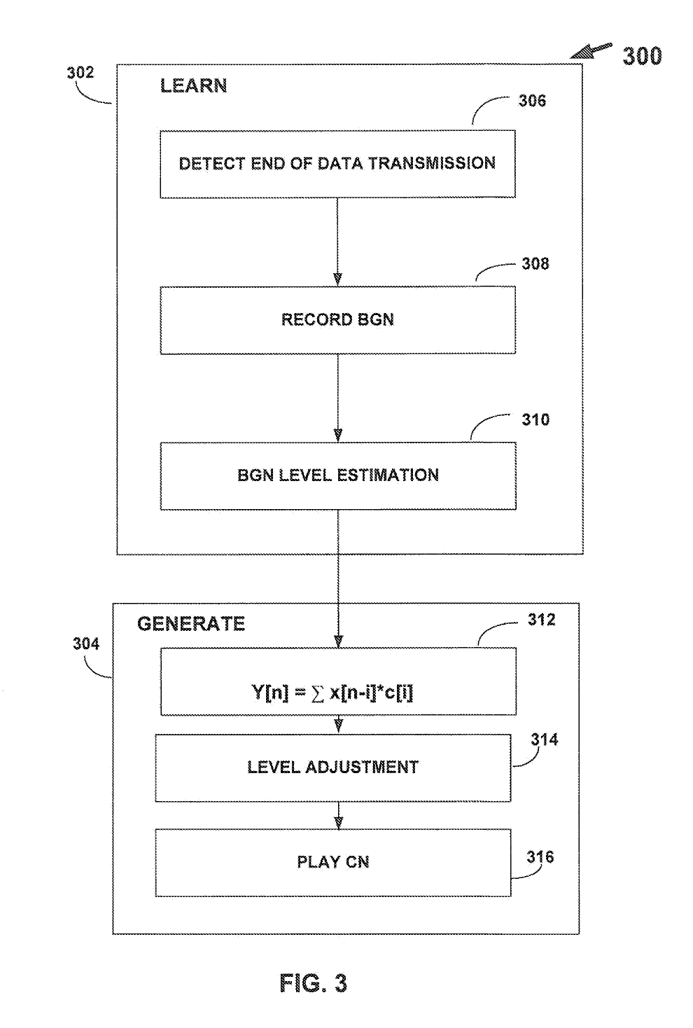

FIG. 3 shows a flow chart of the steps of CNG learn 302 and CNG generate 304 in accordance with the disclosed subject matter. FIG. 3 refers to a general communication network as shown in FIG. 1 that employs DTX. In an exemplary embodiment according to the disclosed subject matter the receiver-end detects the end of data transmission (306), such end of transmission detection is known in the art and may be implemented in various methods, for example by VAD (Voice Activity Detection) or by a message that is transmitted from the transmitter end 104 at the end of transmission. At the end of transmission the receiver starts to record background noise (BUN) (308) during some hangover time referred as time of learning (TL) below. It should be noted that recording background information refers to a general process of recording or collecting information of background noise as known in the art.

It should be noted that while in an exemplary embodiment according to the disclosed subject matter, recording BGN is performed when detecting end of data transmission during TL period, recording BGN may be performed continuously in a cyclic buffer, while usage of the recorded BGN will be controlled by pointers to the relevant sections in the buffer.

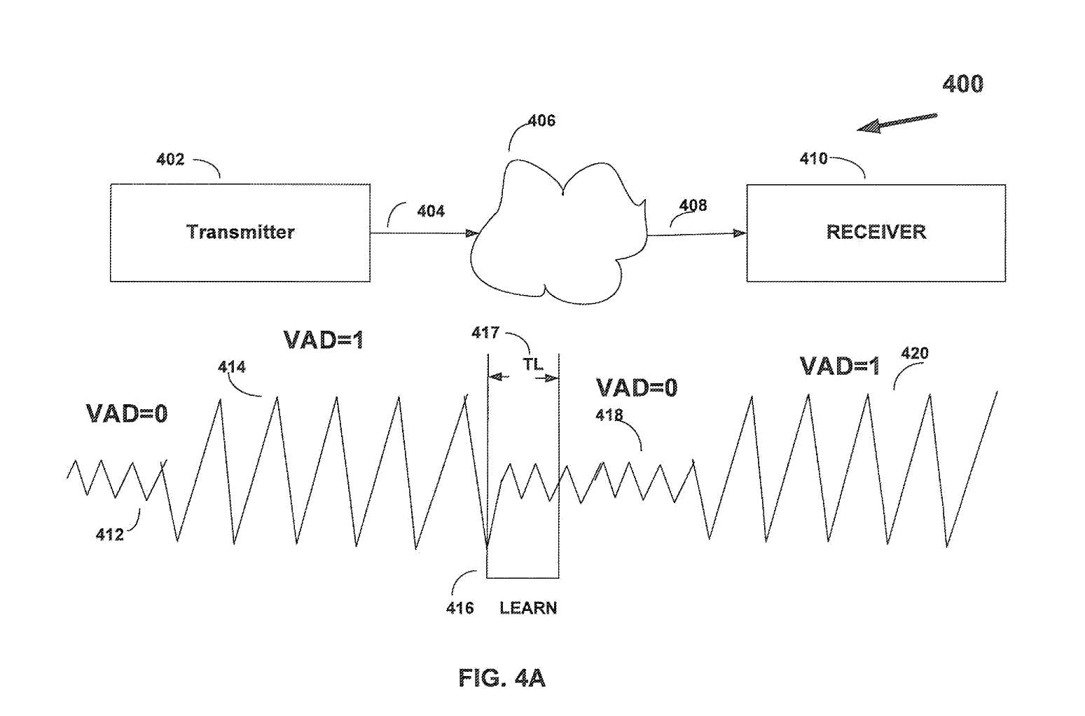

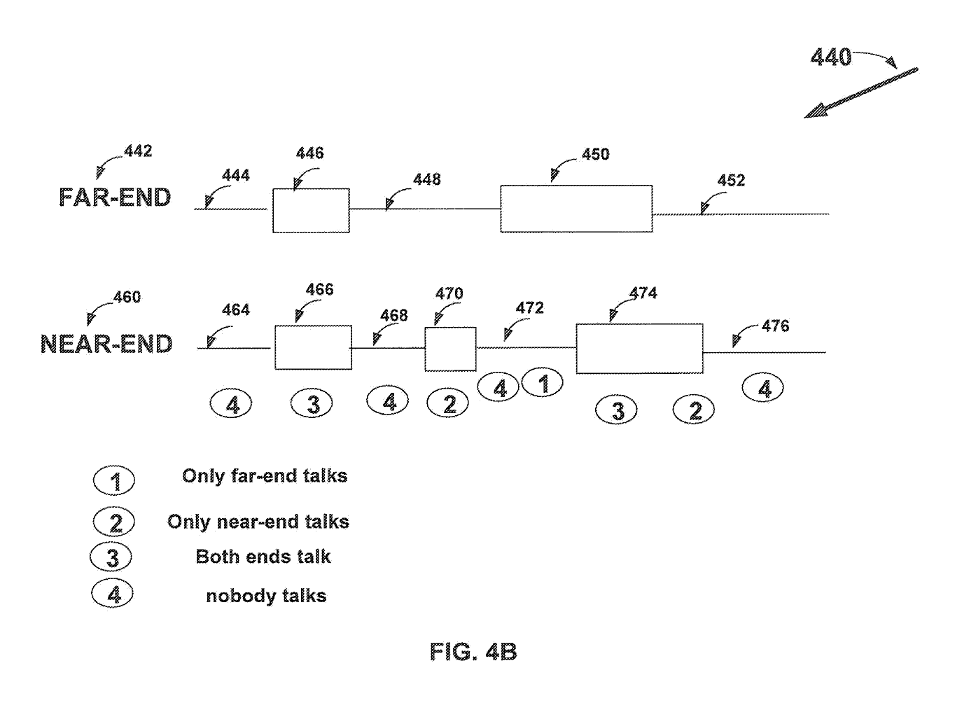

When referring to FIG. 1, recording BGN is performed when data transmission stops and BGN is transmitted from transmitter 104 to receiver 112—a detailed timing scheme will be described with reference to FIG. 4.

When referring to FIG. 2 (A, B or C) BGN is recorded when echo canceller control unit 214 detects for example a case of nobody speaking (only BGN is sent from microphone 207 towards speaker 225.

In order to enable comfort noise generation that has good level matching with the background, a BGN level estimation is performed (310) and level information of the BGN is recorded.

The generate phase of CNG 304 is performed at a later stage when using or playing artificial BGN is required. The generate phase (312) is applied by implementing the convolution following formula:

$$Y ( n ) = {\sum }_{i = 0}^{N - 1} {C ( i )}^{*} X ( n - i ) \qquad ( 1 )$$

Where Xn is the n-th sample of a white-noise signal and wherein C[i] is the ith-sample of the BGN that was recorded at the learn phase. Obviously, in order to get an artificial BGN that meets the basic requirements of spectral matching—the sampled BGN that is recorded at the learn phase 302 should be of a minimal predefined length. In the frequency domain the convolution is transformed to multiplication of the two signals, hence the spectrum of the result is similar to the spectrum of the BGN and therefore there is a perfect spectral matching between the BGN and the generated Comfort Noise. It should be noted that in order to guarantee good matching, it is required to use a relatively big buffer that supports the storage of enough coefficients C[i]. While white-noise could be generated by many methods that are well known to persons that are skilled in the art, thus, this disclosure will not refer to the techniques of generating white noise. It is assumed that white noise is generated by any method and the samples Xn of the white-noise are stored and available for use as described above.

This method of generating artificial background noise is very simple—it requires only a buffer for storing background noise and a simple circuit that implements equation (1) as described above. Since this method uses real background data for generating comfort noise, the generated comfort noise has perfect spectral matching with actual BGN and precise spectral shaping, it has successful track of changes in the actual BGN. (It is continuously updating according to actual BGN), it does not suffer stability problems, there is no need to estimate excitation signal and there is no need to model the spectral envelope. Furthermore, white noise input signal eliminates any non-naturality and repetition.

It is readily understood by persons skilled in the art, that many variations of equation (1) will still yield a good CN. Therefore it should be noted that while equation (1) describes a single formula for generating comfort noise, the invention is not limited to the specific equation as shown by equation (1) and includes any variation on equation (1) that is based on combinations of white noise and samples of real BGN.

Before playing the CN a level adjustment is performed (314) by estimating the actual level of the BGN and adjusting the CN level accordingly. Finally CN is played by the system (316). It should be noted that while level adjustment (314) is shown in FIG. 3 in a specific location in the flowchart level adjustment gain can be applied everywhere to equation (1) since this is a linear system. It can be applied as a factor to the output y, to the input x, to the coefficients c. The level of white noise x, is known a priori.

FIG. 4A is a schematic description 400 of the timing when BGN is recorded in an exemplary embodiment in accordance with the disclosed subject matter. FIG. 4A describes an exemplary timing scheme that is applicable for a communication network that uses CN for filling silence period in discontinuous transmission (DTX) as shown in FIG. 1. The upper part of FIG. 4A shows a schematic system that includes a transmitter 402, a medium (air) 406 and a receiver 410. The lower part of FIG. 4 shows the transition between VAD0 (voice activity is not detected) and VAD1 (voice activity detected) and the timing when the learn phase takes place. In an exemplary scenario as shown in FIG. 4, there is a VAD0 period 412 followed by VAD1 period 414. When VAD1 period ends, the transmitter keeps transmitting for a Time of Learning (TL) period 417 which is used as the learn phase. During this period the receiver samples the background noise to enable the storage of background noise samples to be later used as C[i] coefficients. When TL period is over the transmitter may stop its transmission returning to the normal VAD0 418, until VAD1 starts again 420. During this time 418, CNG is in CNG generate phase.

FIG. 4B is a schematic description 440 of the four mutual states in an echo cancelling system as were described with reference to FIG. 2A. FIG. 4B describes an exemplary timing scheme that is applicable for echo cancelling systems. FIG. 4B shows two time-axes. A first time-axis showing the periods in which a far-end 442 is active, and a second time-axis showing the periods when near-end 460 is active. According to an exemplary scenario, far-end 442 starts as inactive 444, turns active 446, inactive 448, active 450 and ends as inactive 452. Near end is active at periods 466 470 and 474 and is inactive at periods 464, 468, 472 and 476. As was previously described, at times when only BON is present in the system (case 4—when nobody talks), the CNG system is in a learn phase and is recording the BGN. This is shown in FIG. 4B at the overlapping of 444 and 464, 448 and 468, 448 and 472, 452 and 476. The case (1) when only far-end is active, is shown when 450 and 472 are overlapping, in this case CNG is played.

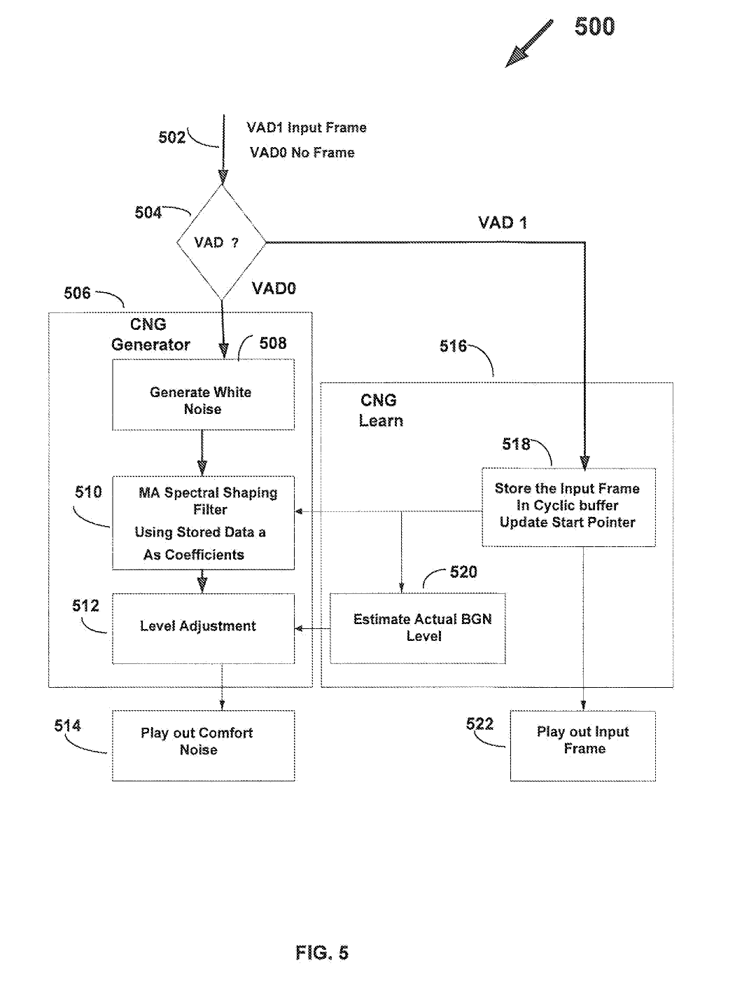

FIG. 5 is a flow chart describing the steps of implementing CNG for replacing silence in the receiver in a network during DTX in accordance with the disclosed subject matter.

FIG. 5 relates to systems such as open DTX systems (such as generally shown in FIG. 1) where both CNG learn and CNG generate are performed in the decoder end, VAD is performed at the encoder 106 (or generally in the transmitter 104) but a message is not transmitted explicitly to the receiver 112. The gap in the transmission indicates VAD0. It is assumed that transition between VAD1 and VAD0 (in the encoder) has enough hangover time to fill a cyclic buffer successfully (marked as TL 417 in FIG. 4).

In an exemplary embodiment, according to the disclosed subject matter, the status of the input frame 502 is checked 504 to determine its VAD (Voice Activity Detection) status. If a voice transmission is detected (VAD1) the input frame enters a CNG LEARN block 516. At the CNG learn block the input frame is stored in a cyclic buffer and a start pointer is updated to point to the recently stored frame 518. It should be noted that it is not necessary to use a cyclic buffer. In another embodiment where VAD state is explicitly transmitted to the receiver or VAD is implemented in the receiver, alternatively a buffer can be filled only at times when a VAD1 to VAD0 transition is detected.

The input frame is then played out, as it was received 522 (during VAD1 the output is not influenced by CNG circuit). In the CNG LEARN there is also a unit for actual BGN level estimation 520 whose output is being used in the CNG generator 506. BGN Level estimation can be done continuously during any step of CNG Learn or alternatively can be done only during VAD1 to VAD0 transition, using the last updated buffer.

When a VAD0 is detected, input frame 502 is ignored and the circuit generates white noise (WN) 508 with a known level. While WN generation is known in the art and may be created by various methods and circuits, the process of creating WN is not described in this disclosure. The WN that was generated in block 508 together with coefficients C[i] that are samples of BGN from the stored input frame 518 are used to produce a Comfort Noise (CN) 510 using the formula:

$$Y ( n ) = {\sum }_{i = 0}^{N - 1} {C ( i )}^{*} X ( n - i )$$

Where i goes from 0 to (N−1), where N is the buffer size that stores the samples C[i] and X[n] are white noise samples. As a person skilled in the art readily understands, in order to produce CN that has good spectral matching characteristic it is necessary to use a relatively long buffer to store the incoming frames. The buffer's length determines the number of coefficients that are used for producing each bit of the CN. (A certain size of buffer is required for preventing the stream from repeating itself, in order to provide naturalness and in order to represent a good frequency response of the actual background noise).

After implementing the above formula a level adjustment block 512 is adjusting the level of the CN according to the estimated actual BGN level, as it is provided by estimate actual BGN level block 520. This is important for providing a CN that has good spectral matching and also good level matching.

Finally the CNG is played out as CN 514 during the VAD0 period.

It should be noted that while FIG. 5 shows an exemplary embodiment with a VAD unit 504, the same functionality can be achieved by other methods, for example, if a message is send from the transmitter (FIG. 1 104) to the receiver (FIG. 1 112) notifying the receiver that a voice/speech/information is about to stop.

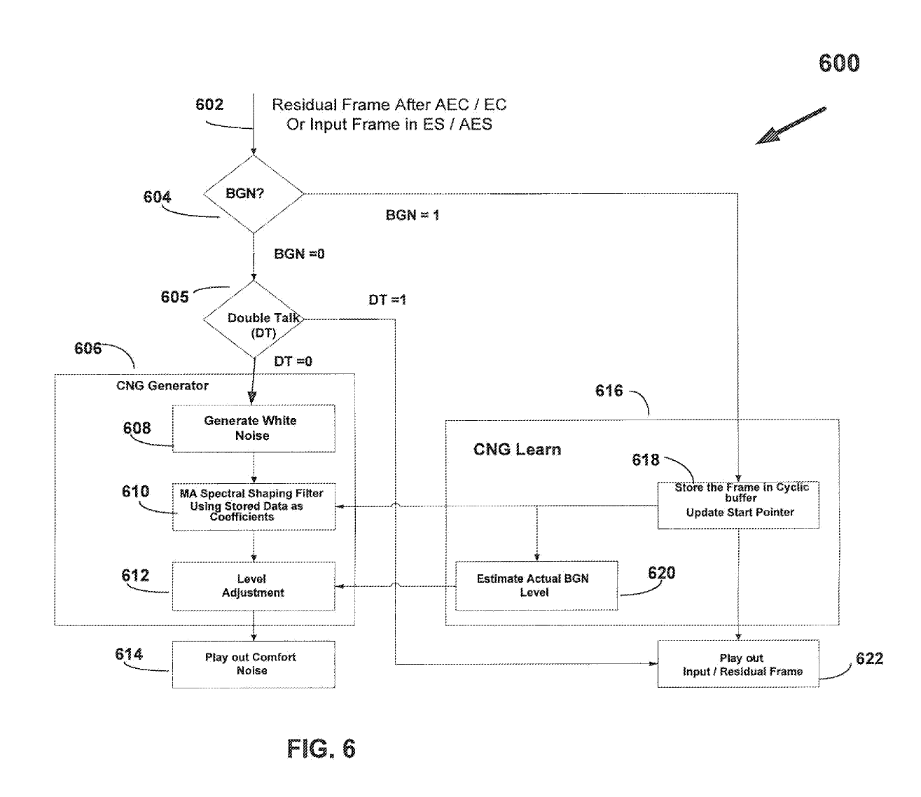

FIG. 6 is a flow chart describing the steps of implementing CNG for replacing residual echo in an audio system that includes an echo canceling function in accordance with the disclosed subject matter (such as generally shown in FIG. 2A, 2B, 2C), FIG. 6 includes many blocks that were already described with reference to FIG. 5 thus; the numerals 606, 608, 610, 612, 614, 616, 618, 620 and 622 are identical to the numerals 506, 508, 510, 512, 514, 516, 518, 520 and 522 respectively.

FIG. 6 refers to a circuit that implements an echo canceling as described in FIG. 2 (A,B and C). There are four cases/states in the circuit that is described in FIG. 2 (A,B and C):
1. Only far end (FE) speaks—There is an echo of far end plus BGN (Shown as BGN=0, DT=0 in FIG. 6 also shown as state 1 in FIG. 4B).
2. Only near end (NE) speaks—NE plus BGN. (Shown as BGN=0, DT=1 in FIG. 6 also shown as state 2 in FIG. 4B).
3. Both FE and NE speak—echo of FE plus NE plus BGN. (BGN=0, Shown as DT=1 in FIG. 6 also shown as state 3 in FIG. 4B).
4. Nobody speaks—only BGN (shown as BGN=1 in FIG. 6 also shown as state 4 in FIG. 4B).
   CN generation according to the disclosed subject matter is applicable when the system is in state one (Only FE speaks). In this case it is desired that FE will hear a BGN (As silence provides an uncomfortable feeling to the FE listener) during NLP suppression.

In an exemplary embodiment in accordance with disclosed subject matter, a residual frame after Acoustic Echo Cancelling (AEC) or Echo Cancelling (EC) (as shown in FIG. 2B 216) or input frame in Echo suppressing (ES) or Acoustic Echo suppression (AES) (as shown in FIG. 2A 210 and 2C 210) is received in the system 602. If the frame is a BGN, as checked in 604, the frame enters a CNG LEARN block 618 undergoing the same process as explained with reference to FIG. 5. State (4) above refers to periods when nobody speaks. However, it may refer to systems that do not handle speech but general/other type of voice/audio information, thus state (4) refers generally to periods when both parties (near and far ends) are inactive (not transmitting meaningful information).

If the input frame is not a BGN (BGN=0) it is checked whether it is double-talk (DT) or not. If it is DT (Not case one) the input frame is played out as is. (In this case when BGN=0 there is no reason to store the frame as the frame storage is performed in order to record BGN and extract C[i] coefficients of BGN).

If the input frame is found to be not a DT (This case of both BGN=0 and DT=0 is indication that the system is in state one where only FE is speaking) it goes into the CNG generator block 606 and undergoes the same path as was described with reference to FIG. 5.

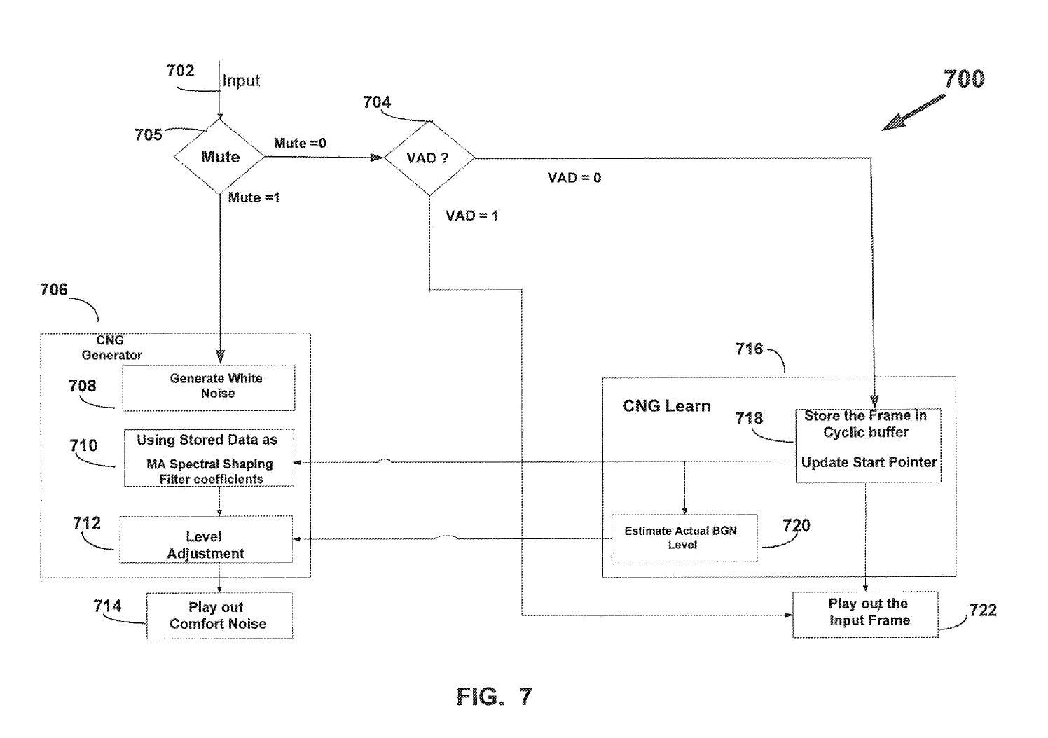

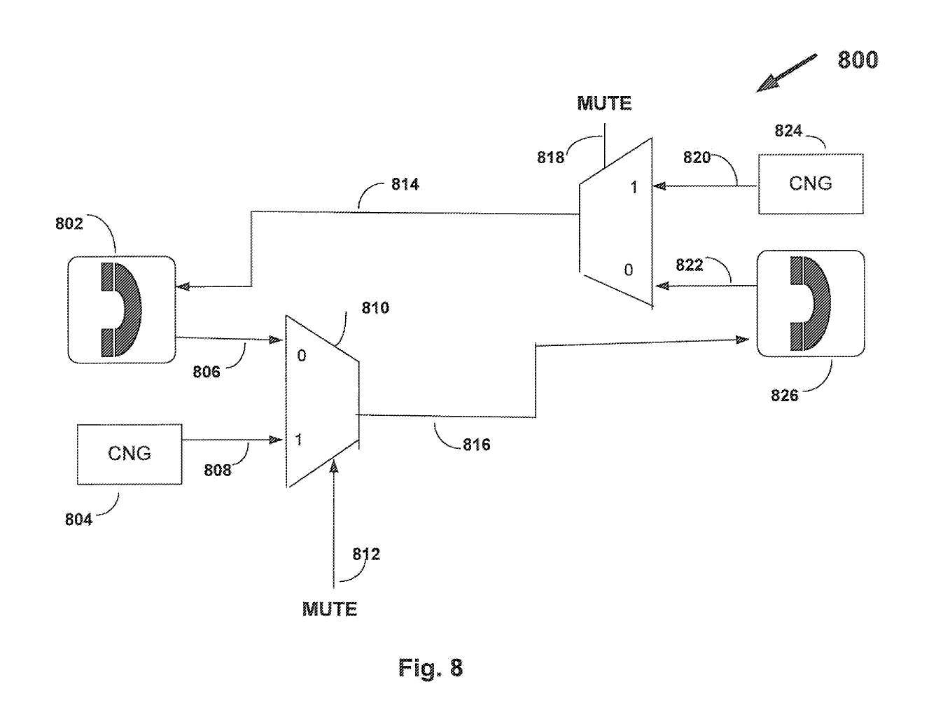

FIG. 7 is a flow chart describing the steps of implementing CNG in a phone system that implements a mute function in accordance with the disclosed subject matter.

FIG. 7 shows an input 702 that is checked 705 to define if a Mute function is active. In case that a Mute function is not active the input is checked to define VAD=0 (no voice activity) or VAD=1 (voice activity detected) 704. In case that VAD=1 the input (typically a frame) is played out 722. If VAD=0 the input (frame) goes into a CNG Learn block 716 and is stored in a buffer, preferably a cyclic buffer and the start pointer of the buffer is updated accordingly. 718 the input is also played out 722 and simultaneously it is used for estimating background noise level 720 (to be applied at times when the Mute function is active).

When the Mute function is active the a White Noise Generator 708 is activated (White noise generation is known in the art and could easily be implemented by a person skilled in the art, hence its implementation is not described in the present disclosure). The white noise is than processed 710 712 in the same way as was described in FIG. 5 510 512, FIG. 6 610,612 and played out as comfort noise 714.

FIG. 8 is a block diagram describing the usage of CNG in a phone system that implements a mute function. Phone user 802 may send to the other user 826 either a speech signal 806 or a CN signal 808 that is generated in a CN generation unit 804. The selection between speech signal 806 and CN signal 808 is defined by the system state, if mute function is activated 812 than CN signal 808 is selected to be sent from the muted user 802 to the other user 826, while when mute function 812 is not activated, speech signal 806 is selected by selector unit 810 to be sent to the other user 826. However, when mute function 812 is not activated the CN is set to its learning phase, i.e. recording BGN (as described in FIG. 7). According to an exemplary embodiment of the disclosed subject matter, the same mechanism is applied with reference to the other user 826.

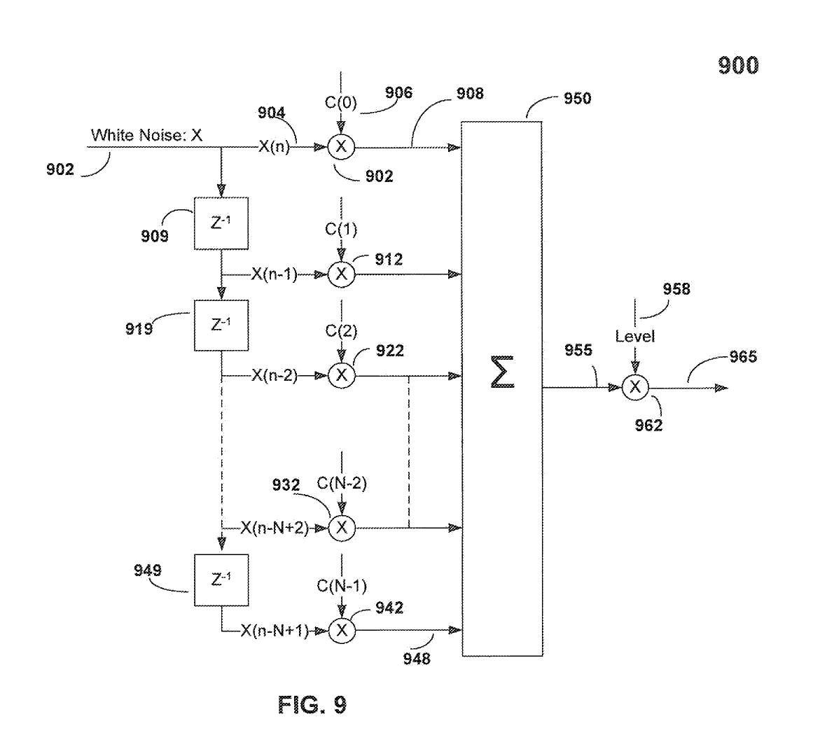

FIG. 9 is a general description of a circuit that implements comfort noise generator function in accordance with the disclosed subject matter.

FIG. 9 shows White Noise 902 being processed in a circuit 900 that uses N coefficients (C(0)−C(N−1)) (These coefficients are taken from the background noise that was previously recorded/stored for example FIG. 5 518, FIG. 6 618, FIG. 7 718). C(0) 906 is multiplied by X(n) 904, C(1) is multiplied by x(n−1) until C(N−1) that is multiplied by X(n−N+1), (x(n−1) represents one unit delay/sample by passing delay unit Z⁻¹ 909, until x(n−N+1) that undergoes N−1 delay units where the last delay unit is marked as 949) All N products (marked for example as 908, 948) are summed in a summation (adder) unit 950 and the result 955 is multiplied by a level estimation coefficient 958, To result with a CN output 965.

While FIG. 9 shows a general description of a circuit that implements comfort noise generator function, it should be noted that a person skilled in the art will readily understand that the circuit that is shown in FIG. 9 could be implemented by a software program (running on any type of a core), alternatively it may be implemented by hardware (using registers, state-machines, combinatorial logic etc.), or be a combination of software and hardware elements.

It should be appreciated that the above described methods and systems may be varied in many ways, including omitting or adding steps, changing the order of steps and the type of devices used. It should be appreciated that different features may be combined in different ways. In particular, not all the features shown above in a particular embodiment are necessary in every embodiment of the invention. Further combinations of the above features are also considered to be within the scope of some embodiments of the invention.

Section headings are provided for assistance in navigation and should not be considered as necessarily limiting the contents of the section.

It will be appreciated by persons skilled in the art, that the present invention is not limited to what has been particularly shown and described hereinabove. Rather the scope of the present invention is defined only by the claims, which follow.

1. A method for Comfort Noise Generation (CNG) comprising the steps of:
(a) recording information of Background Noise (BGN);
(b) generating white noise samples; and
(c) generating Comfort Noise (CN) by applying coefficients that are extracted from said information of BGN on White Noise (WN) samples.

2. The method of claim 2, wherein the Step of recording information of Background Noise includes estimation of actual BNG level, and the step of generating Comfort Noise (CN) by applying coefficients that are extracted from said information of BGN on White Noise (WN) samples includes level adjustment according to said estimation of actual BNG level.

3. The method of claim 2, wherein applying coefficients that are extracted from said information of BGN on White Noise (WN) for generating the n'th sample of CN is performed by implementing a formula that is basically
$$Y ( n ) = {\sum }_{i = 0}^{N - 1} {C ( i )}^{*} X ( n - i )$$
wherein i goes from 0 to N−1, where N is the number of coefficients of each BGN sample, C[i] is the n'th sample of the recorded information of BGN, and X[n] is the n'th sample of the WN.

4. The method of claim 1, wherein the CNG is used in a communication network with discontinuous transmission in order to fill silence periods, the communication network comprising a transmitter and a receiver and wherein the information of BGN is recorded during a predefined period that starts at the beginning of a silence period and wherein the transmitter keeps transmission for enabling the receiver to collect information on the BGN.

5. The method of claim 4, wherein the CNG is used during silence periods, when the transmitter does not transmit data to the receiver.

6. The method of claim 1, wherein the CNG is used in an echo canceller system having a near-end and a far-end; wherein the Background noise (BGN) is recorded during periods when both far-end and near-end are inactive.

7. The method of claim 6, wherein the Comfort Noise (CN) replaces residual echo at times when only far end is active.

8. The method of claim 1, wherein the CNG is used in a communication system that implements a mute function by a muted user, for providing a listener to the muted user with Comfort Noise during periods of the mute function activation.

9. The method of claim 8, wherein BGN is recorded during periods when the mute function is inactive and both the muted user and the listener are inactive; and wherein the CNG is activated during periods when the mute function is activated.

10. The method of claim 2, wherein recording information of Background Noise is implemented by a cyclic buffer with a pointer that tracks the most updated background noise information.

11. The method of claim 2 wherein the generation of Comfort Noise is implemented by software.

12. The method of claim 2 wherein the generation of Comfort Noise is implemented by hardware.

13. The method of claim 2 wherein the generation of Comfort Noise is implemented by a combination of software and hardware elements.

14. A system for Comfort Noise Generation, comprising:
(a) A unit for recording information of Background Noise (BGN) during periods when only BGN is present;
(b) A White-Noise generation unit;
(c) A unit for generating Comfort Noise (CN); wherein the CN is generated by applying coefficients that are extracted from said information of BGN on White Noise (WN) samples that were generated by said White-Noise generation unit.

15. The system of claim 15, wherein the unit for recording information of Background Noise (BGN) includes a functionality of estimation of actual BNG level, and wherein the unit for generating CN includes level adjustment according to said estimation of actual BNG level.

16. The system according to claim 15, wherein the unit for generating Comfort Noise implements a function that is basically described by the formula
$$Y ( n ) = {\sum }_{i = 0}^{N - 1} {C ( i )}^{*} X ( n - i )$$
